(19) United States
(12) Patent Application Publication
(10) Pub. No.: US 2008/0280215 A1
(43) Pub. Date: Nov. 13, 2008

(54) METHOD OF FORMING PHOTOMASK OF SEMICONDUCTOR DEVICE

(75) Inventor: Jae Cheon Shin, Chungcheongbuk-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/962,421

(22) Filed: Dec. 21, 2007

(30) Foreign Application Priority Data
May 11, 2007 (KR) 10-2007-0045795

(51) Int. Cl. G03F 1/00

(52) U.S. Cl. 430/5

(57) ABSTRACT

A method of forming a photomask of a semiconductor device includes depositing a first phase shift layer, a light blocking layer, and a second phase shift layer on a transparent substrate, and then a first photoresist pattern is formed to expose a region on an upper surface of the second phase shift layer. Then, the exposed region is etched by using the first photoresist pattern as a mask to form a second phase shift pattern, and the light blocking layer is etched by using the second phase shift pattern as a mask to form a light blocking pattern. Thereafter, a second photoresist pattern is formed on the transparent substrate to define a phase shift region and a light transmitting region. The first phase shift layer is etched by using the second photoresist pattern as a mask to form a first phase shift pattern. Then, the light blocking pattern of the phase shift region is etched to form a phase shift mask pattern.

### CROSS-REFERENCE TO RELATED APPLICATION

The priority of Korean patent application number 10-2007-0045795, filed on May 11, 2007, which is incorporated by reference in its entirety, is claimed.

### BACKGROUND OF THE INVENTION

The invention relates to a semiconductor device, and more particularly, to a method of forming a photomask of a semiconductor device, which method is capable of forming a fine pattern through a correction of the critical dimension (CD).

In a manufacturing process of a semiconductor device, a plurality of photolithography processes are performed in order to form semiconductor devices on the surface of a semiconductor substrate. A photomask with a fine pattern is required to form a highly integrated circuit during the photolithography processes. Additionally, as semiconductor devices are becoming more highly integrated, the demand for CD uniformity increases.

A photomask generally uses a binary mask, where a light blocking layer is formed on a transparent substrate and then is etched in a specific pattern, such that transmitted light can be projected on a wafer only through the specific pattern. Suggested is a half-tone phase shift mask capable of forming a finer pattern than a binary mask by means of a phase shift material with a transmittance of several percent.

FIGS. 1A to 1E illustrate a conventional method of forming a photomask. FIGS. 2 and 3 illustrate limitations while correcting the CD of a pattern.

Referring to FIG. 1A, a phase shift layer 102 is deposited on a transparent substrate 100, and then a light blocking pattern 104 is formed on the phase shift layer 102 to expose a portion of the surface of the phase shift layer 102.

A CD 106b of the light blocking pattern 104 on the phase shift layer 102 is measured. When the measured CD 106b of the light blocking pattern 104 is greater than a desirable CD 106a, the light blocking pattern 104 is overetched to correct its CD 106b. Specifically, a first photoresist pattern 108 is formed to block remaining regions except for regions where the CD 106b is corrected through overetching, by depositing and patterning a photoresist layer on the transparent substrate 100 including the light blocking pattern 104 as illustrated in FIG. 1B.

Referring to FIG. 1C, the light blocking pattern 104 is overetched using the first photoresist pattern 108 as a mask, in order to form a light blocking pattern 110 that is corrected within a desirable range of the CD 106a. Thereafter, the phase shift layer 102 is etched using the light blocking pattern 110 as a mask to form a phase shift pattern 112 exposing a portion of the surface of the transparent substrate 100. During the formation of the phase shift pattern 112, the CD of a pattern can be additionally corrected. In the same manner, the first photoresist pattern 108 can be etched and removed while performing an etching process to correct the CD. Accordingly, the photoresist layer is applied on the transparent substrate 100 to remove the light blocking pattern 110, and then exposure and development processes are performed, such that a second photoresist pattern is formed as illustrated in FIG. 1D. Next, the light blocking pattern 110 is removed using the second photoresist pattern 114 as a mask. Then, when the second photoresist pattern 114 is removed by using a strip process, a phase shift mask pattern 120 including a phase shift region 116 and a light transmitting region 118 is formed on the transparent substrate 100 as illustrated in FIG. 1E. On the other hand, a difference between the pattern and the CD may occur because etching may not be ideally performed when the light blocking pattern 110 is overetched to correct the CD.

Referring to FIG. 2, a portion 108a of the first photoresist pattern 108 may remain on the side of the light blocking pattern 104 when the first photoresist pattern 108 is formed on the transparent substrate 100 in order to correct the CD by overetching the light blocking pattern 104. Due to the portion 108a of the first photoresist pattern 108 remaining on the side of the light blocking pattern 104, the etching of the light blocking pattern 104 may not be ideally performed, such that it can cause an etching difference (a) in neighboring patterns. Furthermore, as illustrated in FIG. 3, photoresist scum 108b may remain around the light blocking pattern 104 during the forming of the first photoresist pattern 108. Depending on the amount of the photoresist scum 108b, etching accuracy may not be achieved when the CD is corrected. For example, as the amount of the photoresist scum 108b increases, an etching process for correcting the light blocking pattern 108b may not be properly performed, such that a required CD may not be achieved during etching of the side surface.

### SUMMARY OF THE INVENTION

Embodiments of the invention are directed to a method of forming a photomask of a semiconductor device, which method is capable of forming a fine pattern through a correction of the critical dimension (CD).

In one embodiment, a method of forming a photomask of a semiconductor device includes: depositing a first phase shift layer, a light blocking layer, and a second phase shift layer on a transparent substrate; forming a first photoresist pattern to expose a region on an upper surface of the second phase shift layer; etching the exposed region by using the first photoresist pattern as a mask to form a second phase shift pattern; etching the light blocking layer by using the second phase shift pattern as a mask to form a light blocking pattern; forming a second photoresist pattern on the transparent substrate to define a phase shift region and a light transmitting region; etching the first phase shift layer by using the second photoresist pattern as a mask to form a first phase shift pattern, the first phase shift pattern exposing a portion of an upper surface of the transparent substrate; and etching the light blocking pattern of the phase shift region to form a phase shift mask pattern.

After forming the second phase shift pattern the method preferably further includes: measuring a critical dimension (CD) of the second phase shift pattern; and overetching the second phase shift pattern by using the measured CD to correct the CD to a desirable CD.

After forming the light blocking pattern, the method preferably further includes: measuring a CD of the light blocking pattern; and overetching the light blocking pattern by using the measured CD to correct the CD to a desirable CD.

After forming the first phase shift pattern, the method preferably further includes: measuring a CD of the first phase shift pattern; and overetching the first phase shift pattern by using the measured CD to correct the CD to a desirable CD.

The first and second phase shift layer preferably includes molybdenum silicide (MoSi₂).

### BRIEF DESCRIPTION OF THE DRAWINGS

FIGS. 1A to 1E illustrate a conventional method of forming a photomask.

FIGS. 2 and 3 illustrate limitations of correcting the CD of a pattern.

FIGS. 4A to 4I illustrate a method of forming a photomask of a semiconductor device according to one embodiment of the invention.

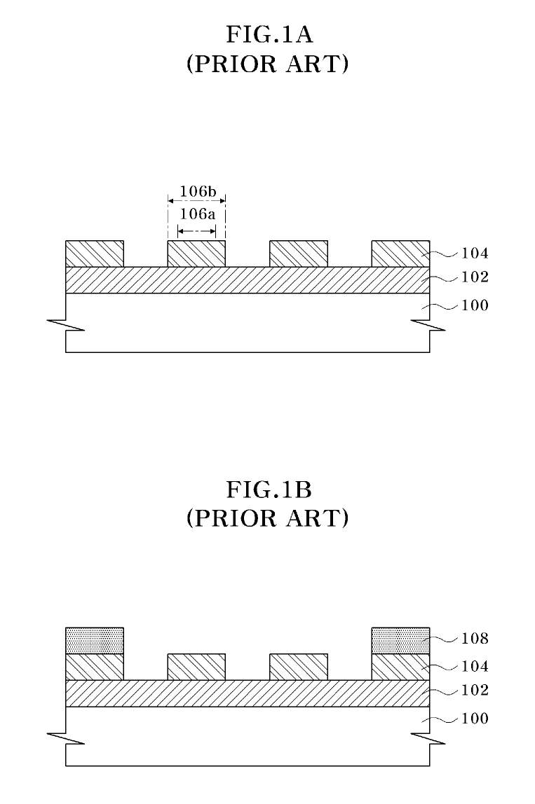

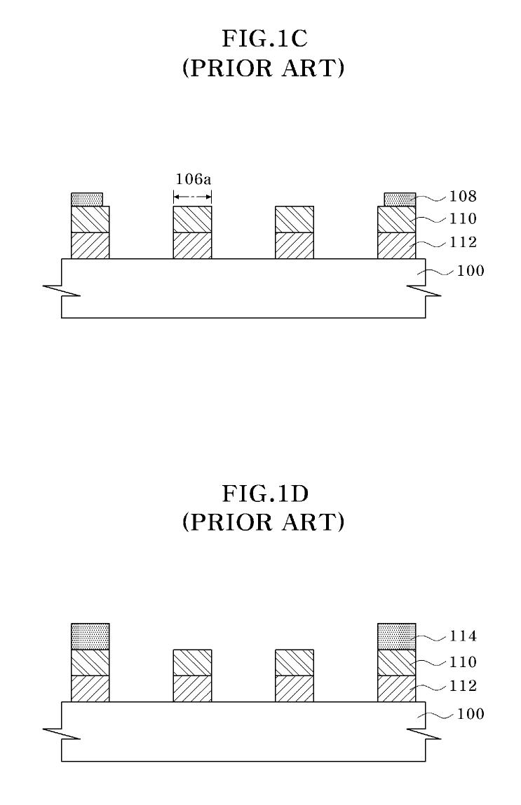

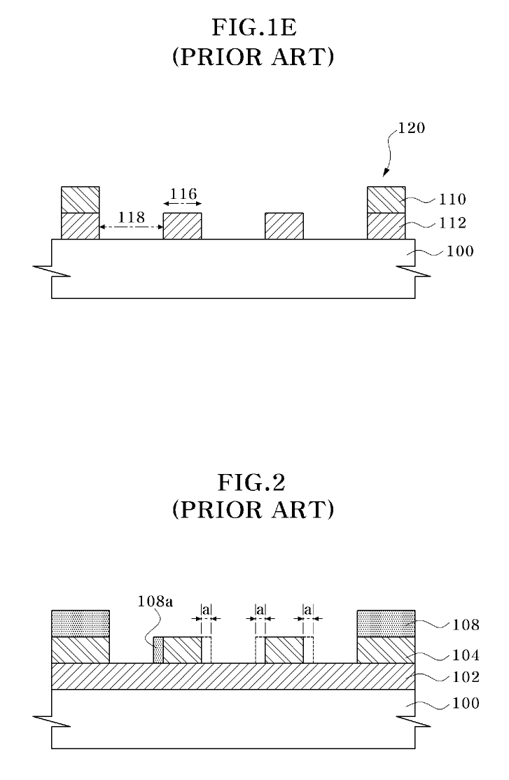

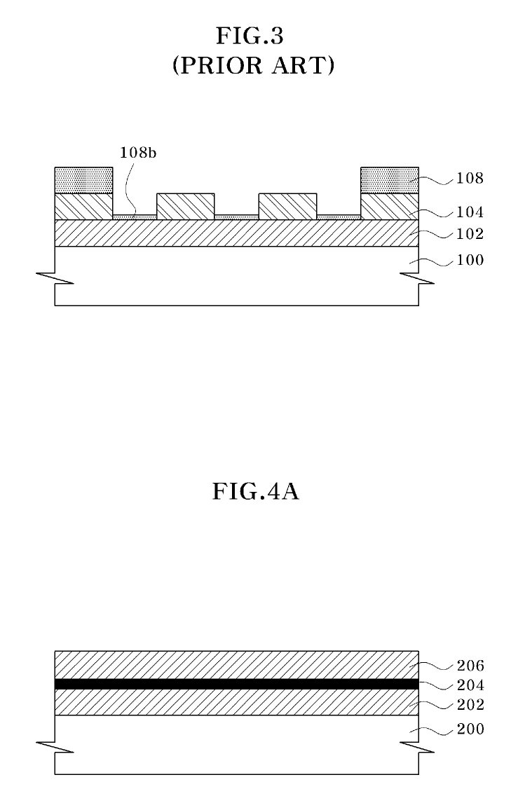

### DESCRIPTION OF SPECIFIC EMBODIMENTS

Hereinafter, a method of forming a photomask of a semiconductor device in accordance with the invention will be described in detail with reference to the accompanying drawings.

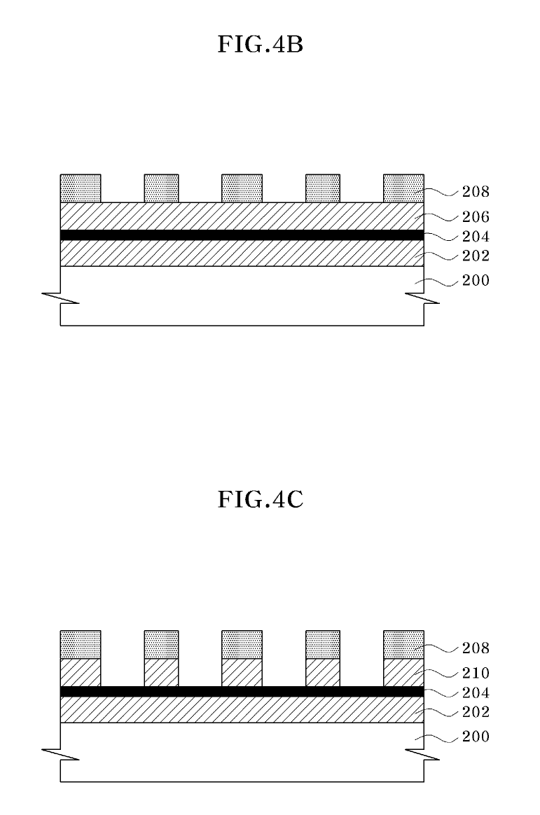

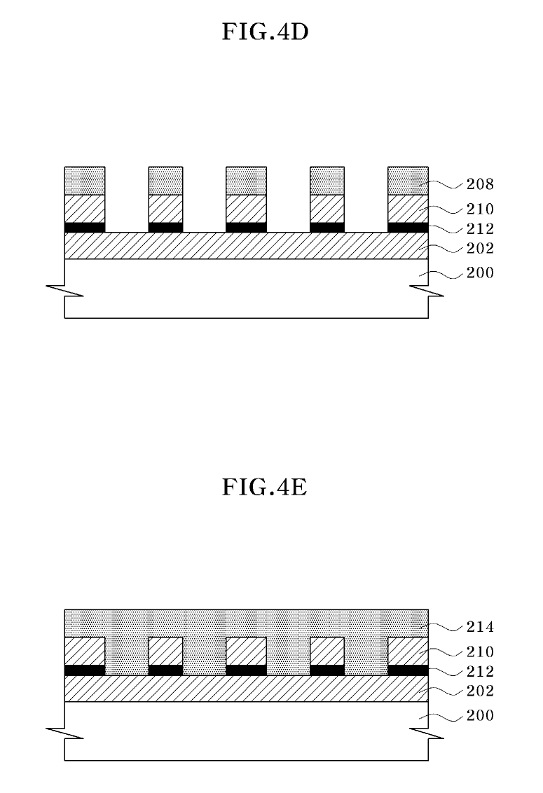

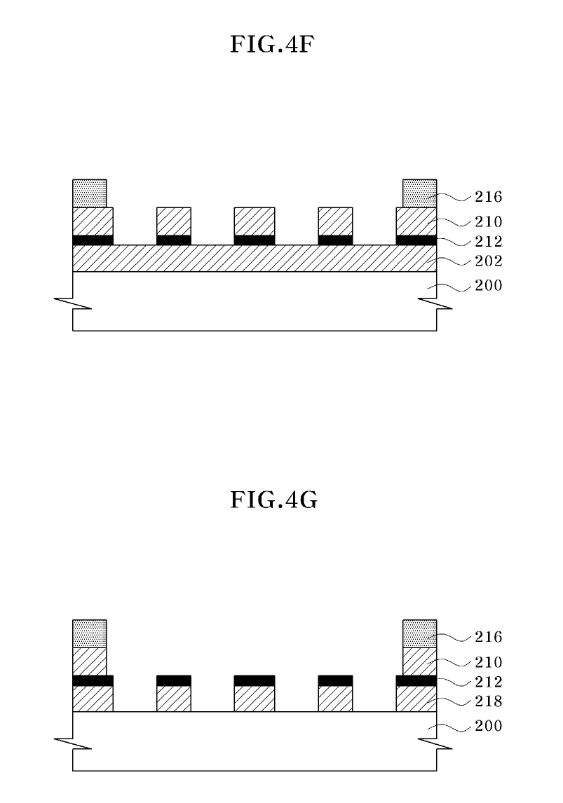

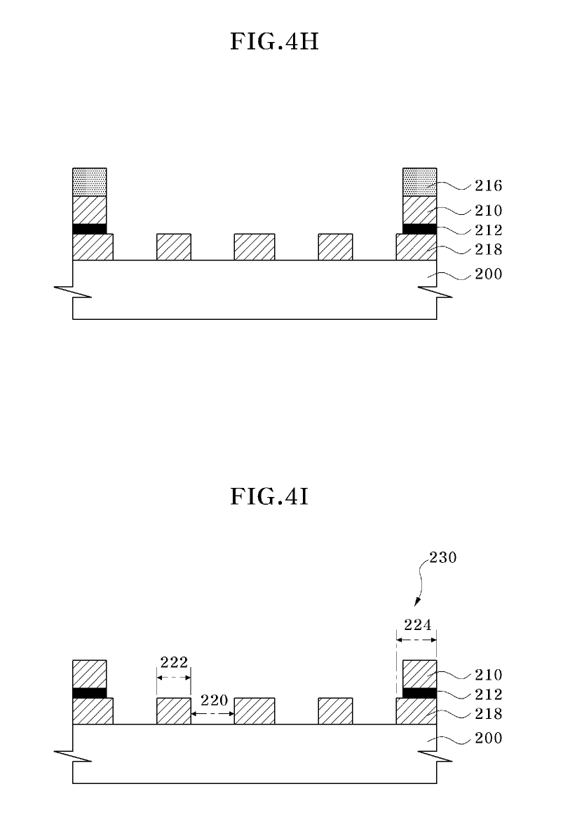

FIGS. 4A to 4I illustrate a method of forming a photomask of a semiconductor device according to one embodiment of the invention.

Referring to FIG. 4A, a first phase shift layer 202, a light blocking layer 204, and a second phase shift layer 206 are sequentially deposited on a transparent substrate 200. The transparent substrate 200 is formed of a transparent material, for example quartz. The first phase shift layer 202 deposited on the transparent substrate 200 is preferably formed of molybdenum silicide (MoSi₂), which is a material that shifts the light phase during the following exposure process. The light blocking layer 204 deposited on the first phase shift layer 202 is a blocking layer that blocks light and is preferably formed of chromium (Cr). A second phase shift layer 206 deposited on the light blocking layer 204 prevents the light blocking layer 204 and the first phase shift layer 202 from being damaged and lost while correcting the critical dimension (CD) of a mask pattern. The second phase shift layer 206 is preferably formed of a material similar to that of the first phase shift layer 202, and may be formed of MoSi₂.

Referring to FIG. 4B, a photoresist layer is coated and patterned on the second phase shift layer 206 to form a first photoresist pattern 208 exposing a portion of the second phase shift layer 206.

Referring to FIG. 4C, the second phase shift layer 206 is etched using the first photoresist pattern 208 to form a second phase shift pattern 210 exposing a portion of the surface of the light blocking layer 204. After forming the second phase shift pattern 210, the CD of the second phase shift pattern 210 is measured by a CD-measuring apparatus. If the measured CD of the second phase shift pattern 210 is greater than the desirable CD, the second phase shift pattern 210 is overetched to correct the measured CD to the desirable CD.

Referring to FIG. 4D, the exposed light blocking layer 204 is etched using the second phase shift pattern 210 to form a light blocking pattern 212. At this point, after forming the light blocking pattern 212, the CD of the light blocking pattern 212 is measured by using a CD-measuring apparatus. If the measured CD of the light blocking pattern 212 is not in the desirable CD range, the CD of the light blocking pattern 212 can be corrected by using a process such as overetching. Next, the first photoresist pattern 208 is removed by performing a strip process.

Typically, a conventional photomask structure includes a transparent substrate, a phase shift layer, a light blocking layer, and a photoresist layer that are sequentially stacked. When etching the light blocking layer in the above structure, the remaining photoresist layer is reduced more, compared to when the phase shift layer is etched. As a result, it is difficult to measure the CD of the layer, and to thus correct the CD to a desirable CD. Moreover, an additional process is required to correct the CD, and correction of the CD can be performed only when the light blocking pattern is formed. Furthermore, when measuring and correcting the CD after the forming of the light blocking pattern, the etching selectivity of the photoresist layer and the light blocking layer is less than that of photoresist layer and the phase shift layer. Accordingly, when measuring the CD of the light blocking pattern during the forming of the light blocking pattern, with the etching loss of the photoresist layer greater than that of the phase shift layer, an electric beam of a scanning electron microscope (SEM) additionally damages the photoresist layer. Therefore, it is difficult to accurately measure the CD, and the correcting of the CD cannot therefore be accurately performed.

According to the one embodiment of the invention, overetching is performed to correct the CD of the light blocking pattern 212 when the second phase shift pattern 210 is deposited on the light blocking pattern 212. Because the light blocking pattern 212 is etched by using the second phase shift pattern 210 as a passivation layer, even if the remaining photoresist layer is reduced, the CD can be measured and corrected. Additionally, the second phase shift pattern 210 on the light blocking pattern 212 serves as a passivation layer, thereby preventing the light blocking pattern 212 from being overly etched and damaged.

Referring to FIG. 4E, a second photoresist layer 214 is formed on the transparent substrate 200. The second photoresist layer 214 defines a light transmitting region and a phase shift region during the formation of a mask pattern.

Referring to FIG. 4F, exposure and development processes are performed on the second photoresist layer 214 to form a second photoresist pattern 216 that exposes a portion of the surface of the first phase shift layer 202 and defines a light transmitting region and a phase shift region.

Referring to FIG. 4G, the first phase shift layer 202 is etched by using the second photoresist pattern 214, the second phase shift pattern 210, and the light blocking pattern 212 as a mask to form the first phase shift pattern 218 that selectively exposes the surface of the transparent substrate 200. At this point, after the forming of the first phase shift pattern 218, the CD of the first phase shift pattern 218 can be measured by using a CD-measuring apparatus. If the measured CD of the first phase shift pattern 218 is not in the desirable CD range, the CD of the first phase shift pattern 218 can be corrected by using a process such as overetching.

Referring to FIG. 4H, the light blocking pattern 212 on the phase shift region is partially removed by etching the light blocking pattern 212. The removal of the light blocking pattern 212 may be performed using wet etching or dry etching.

Referring to FIG. 4I, the second photoresist pattern 216 is removed by performing a strip process to form a mask pattern 230. A region where the surface of the transparent substrate 200 is exposed becomes a light transmitting region 220, and a region where the first phase shift pattern 218 is disposed becomes a phase shift region 222. Additionally, the remaining regions except for the light transmitting region 220 and the phase shift region 222 become a light blocking region 224.

According to the method of forming a photomask of a semiconductor device, the first phase shift layer and the light blocking layer are deposited on the transparent substrate, and then the second phase shift layer is deposited on the light blocking layer. A layer having an excellent etching selectivity with respect to the photoresist layer, e.g., the phase shift layer, is deposited both above and below the light blocking layer as a double layer, such that an accurate CD can be achieved. Additionally, because the second phase shift layer is used as a passivation layer when the light blocking layer is etched after measuring the CD, the CD can be accurately measured regardless of the amount of the remaining photoresist layer. Furthermore, because an additional resist material for CD correction is applied and also the exposure and development processes can be omitted, CD error due to the photoresist scum can be prevented.

The embodiments of the invention have been disclosed above for illustrative purposes. Those skilled in the art will appreciate that various modifications, additions and substitutions are possible, without departing from the scope and spirit of the invention as defined in the accompanying claims.

What is claimed is:

1. A method of forming a photomask of a semiconductor device, the method comprising:
depositing a first phase shift layer, a light blocking layer, and a second phase shift layer on a transparent substrate;
forming a first photoresist pattern to expose a region on an upper surface of the second phase shift layer;
etching the exposed region by using the first photoresist pattern as a mask to form a second phase shift pattern;
etching the light blocking layer by using the second phase shift pattern as a mask to form a light blocking pattern;
forming a second photoresist pattern on the transparent substrate to define a phase shift region and a light transmitting region;
etching the first phase shift layer by using the second photoresist pattern as a mask to form a first phase shift pattern, the first phase shift pattern exposing a portion of an upper surface of the transparent substrate; and
etching the light blocking pattern of the phase shift region to form a phase shift mask pattern.

2. The method according to claim 1, further comprising:
measuring a critical dimension (CD) of the second phase shift pattern after forming the second phase shift pattern; and
overetching the second phase shift pattern by using the measured CD to correct the CD to a desirable CD.

3. The method according to claim 1, further comprising:
measuring a CD of the light blocking pattern after forming the light blocking pattern; and
overetching the light blocking pattern by using the measured CD to correct the CD to a desirable CD.

4. The method according to claim 1, further comprising:
measuring a CD of the first phase shift pattern after forming the first phase shift pattern; and
overetching the first phase shift pattern by using the measured CD to correct the CD to a desirable CD.

5. The method according to claim 1, wherein the first phase shift layer comprises molybdenum silicide (MoSi₂).

6. The method according to claim 1, wherein the second phase shift layer comprises molybdenum silicide (MoSi₂).
